(19) United States
(12) Patent Application Publication
(10) Pub. No.: US 2016/0320451 A1
(43) Pub. Date: Nov. 3, 2016

(54) SIMULATION VERIFICATION METHOD FOR FPGA FUNCTION MODULES AND SYSTEM THEREOF

(71) Applicant: CAPITAL MICROELECTRONICS CO., LTD., Beijing (CN)

(72) Inventors: Yuanpeng WANG, Beijing (CN); Ping FAN, Beijing (CN); Jia GENG, Beijing (CN)

(73) Assignee: CAPITAL MICROELECTRONICS CO., LTD., Beijing (CN)

(21) Appl. No.: 14/758,379

(22) PCT Filed: Dec. 30, 2014
(86) PCT No.: PCT/CN2014/095667

§ 371 Date: Jun. 29, 2015

(51) Int. Cl. G01R 31/317; G01R 31/3177

(52) U.S. Cl. CPC G01R 31/31704; G01R 31/3177; G01R 31/31703

(57) ABSTRACT

A simulation verification method for Field Programmable Gate Array (FPGA) function modules and a system thereof. The method includes: generating all test cases by enumerating all parameter characteristics of FPGA function modules; generating, according to an input type and input parameter characteristics of an FPGA function module under test, a simulation test bench matching configuration of the corresponding FPGA function module under test; and randomly generating, by the simulation test bench, a test stimulus and a corresponding expected output according to the input parameter characteristics of the FPGA function module under test, comparing the expected output with an actual output obtained after the test stimulus is applied to the test case corresponding to the FPGA function module under test, and outputting a test report of the FPGA function module under test according to a comparison result.

### BACKGROUND

1. Technical Field

The present invention relates to Field Programmable Gate Array (FPGA) verification technologies, and in particular, to a simulation verification method for FPGA function modules and a system thereof.

2. Related Art

FPGA verification is a process of testing correctness of design by means of simulation, timing analysis and on-board commissioning. During design of an FPGA chip, in order to ensure consistency of specific function modules in the entire design process, consistency verification on the specific modules is particularly important. The key of behavior simulation, as a common method for consistency verification, is how to enhance test coverage.

### SUMMARY

An objective of the present invention is to provide a simulation verification system that enhances test coverage, so as to solve the technical problem of low coverage existing in behavior simulation.

To achieve the foregoing objective, in one aspect, the present invention provides a simulation verification method for FPGA function modules, the method including: generating all test cases by enumerating all parameter characteristics of FPGA function modules; generating, according to an input type and input parameter characteristics of an FPGA function module under test, a simulation test bench matching configuration of the corresponding FPGA function module under test; and randomly generating, by the simulation test bench, a test stimulus and a corresponding expected output according to the input parameter characteristics of the FPGA function module under test, comparing the expected output with an actual output obtained after the test stimulus is applied to the test case corresponding to the FPGA function module under test, and outputting a test report of the FPGA function module under test according to a comparison result.

Preferably, before the step of comparing the expected output with an actual output obtained after the test stimulus is applied to the test case corresponding to the FPGA function module under test, the method further includes: determining whether the FPGA function module under test is an upgraded module on the basis of an existing function module, if yes, comparing a first value obtained after the test stimulus is applied to the FPGA function module under test with a second value obtained after the test stimulus is applied to the existing function module, and if the first value and the second value are different, reporting an error in simulation; if the first value and the second value are the same, comparing the first value with the expected output, if they are different, reporting an error in the simulation, and if they are the same, reporting that the simulation succeeds.

In another aspect, the present invention provides a simulation verification system for FPGA function modules, the system including: a verification bench control center, where the verification bench control center is used for generating all test cases by enumerating all parameter characteristics of FPGA function modules; and generating, according to an input type and input parameter characteristics of an FPGA function module under test, a simulation test bench matching configuration of the corresponding FPGA function module under test; and randomly generating, by the simulation test bench, a test stimulus and a corresponding expected output according to the input parameter characteristics of the FPGA function module under test, comparing the expected output with an actual output obtained after the test stimulus is applied to the test case corresponding to the FPGA function module under test, and outputting a test report of the FPGA function module under test according to a comparison result.

Preferably, the verification bench control center includes a test case generator and a test bench generator, where the test case generator is used for generating all test cases by enumerating all parameter characteristics of FPGA function modules; and the test bench generator is used for generating, according to an input type and input parameter characteristics of an FPGA function module under test, a simulation test bench matching configuration of the FPGA function module under test.

Preferably, the simulation test bench includes a random stimulus generator and a comparator, where the random stimulus generator is used for, randomly generating a test stimulus and a corresponding expected output according to the input parameter characteristics of the FPGA function module under test; and the comparator is used for comparing the expected output with an actual output obtained after the test stimulus is applied to the test case corresponding to the FPGA function module under test, and outputting a test report of the FPGA function module under test according to a comparison result.

Preferably, the simulation test bench includes a random stimulus generator and a dual comparator, where the random stimulus generator is used for randomly generating a test stimulus and a corresponding expected output according to the input parameter characteristics of the FPGA function module under test; and the dual comparator is used for determining whether the FPGA function module under test is a module upgraded on the basis of an existing function module, if yes, comparing a first value obtained after the test stimulus is applied to the FPGA function module under test with a second value obtained after the test stimulus is applied to the existing function module, and if the first value and the second value are different, reporting an error in simulation; if the first value and the second value are the same, comparing the first value with the expected output, if they are different, reporting an error in the simulation, and if they are the same, reporting that the simulation succeeds.

In the present invention, all test cases are acquired based on information about all parameter characteristics of FPGA function modules, thereby establishing a simulation verification system with test coverage reaching 100%.

### BRIEF DESCRIPTION OF THE DRAWINGS

FIG. 1 is a flow chart of a simulation verification method for FPGA function modules according to an embodiment of the present invention;

FIG. 2 is a schematic diagram of a process of generating a test case of an FPGA module;

FIG. 3 is a schematic diagram of a process of generating a simulation test bench of an FPGA module;

FIG. 4a is a schematic diagram of a simulation verification process of an FPGA module;

FIG. 4b is a schematic diagram of another simulation verification process of an FPGA module; and

FIG. 5 is a structural diagram of a simulation verification system for FPGA function modules according to an embodiment of the present invention.

### DETAILED DESCRIPTION

The technical solution of the present invention is further described below in detail with reference to the accompanying drawings and embodiments.

FIG. 1 is a flow chart of a simulation verification method for FPGA function modules according to an embodiment of the present invention. As shown in FIG. 1, the method includes steps 101 to 103.

Step 101: Generate all test cases by enumerating all parameter characteristics of FPGA function modules.

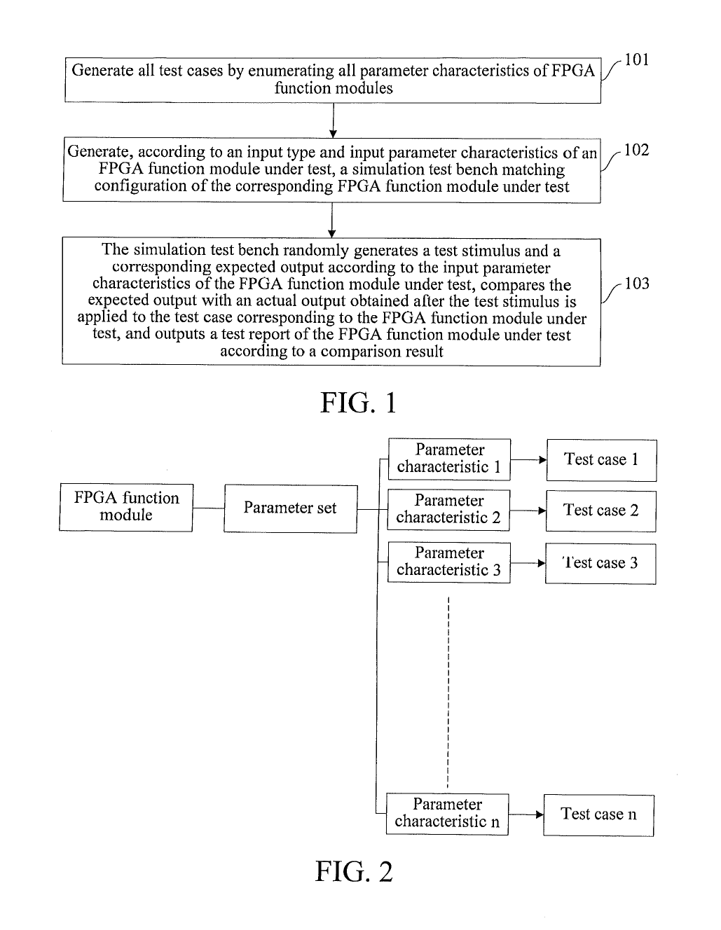

Specifically, a simulation verification system generates all test cases by enumerating all parameter characteristics of different FPGA function modules, such as a phase-locked loop module, a digital processor module, a configurable logic block and a memory module (as shown in FIG. 2).

Step 102: Generate, according to an input type and input parameter characteristics of an FPGA function module under test, a simulation test bench matching configuration of the corresponding FPGA function module under test.

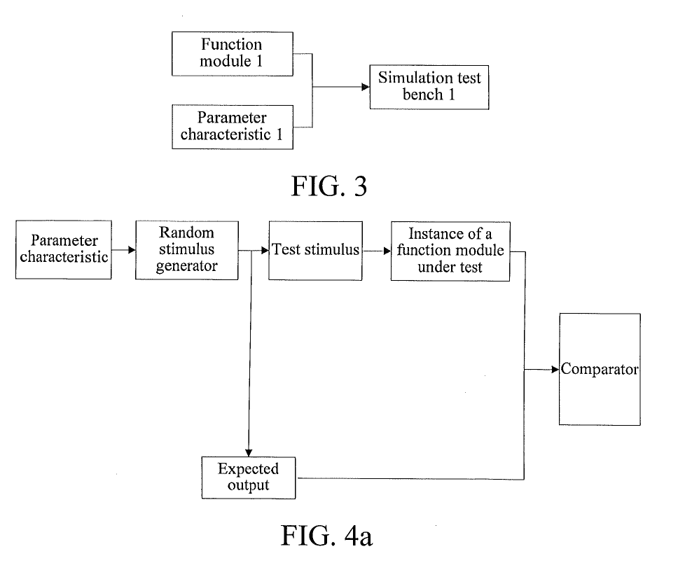

Specifically, the simulation verification system generates, according to an input type and input parameter characteristics of an FPGA function module under test, a simulation test bench matching configuration of the corresponding FPGA function module under test (as shown in FIG. 3).

Step 103: The simulation test bench randomly generates a test stimulus and a corresponding expected output according to the input parameter characteristics of the FPGA function module under test, compares the expected output with an actual output obtained after the test stimulus is applied to the test case corresponding to the FPGA function module under test, and outputs a test report of the FPGA function module under test according to the comparison result.

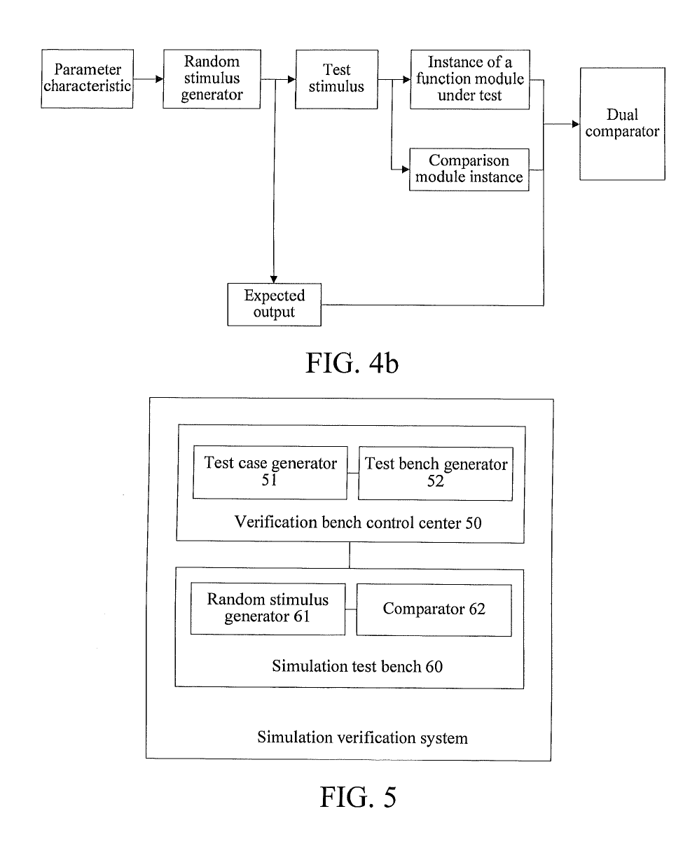

Specifically, the simulation test bench randomly generates a test stimulus and a corresponding expected output according to the input parameter characteristics, applies the generated test stimulus to the test case corresponding to the FPGA function module under test (that is, an instance of a function module under test), compares an output result with the expected output, and outputs a test report of the FPGA function module under test according to a comparison result (as shown in FIG. 4a).

Preferably, before the step of comparing the expected output with an actual output obtained after the test stimulus is applied to the test case corresponding to the FPGA function module under test, the simulation test bench further determines whether the FPGA function module under test is a module upgraded on the basis of an existing function module, if yes, compares a first value obtained after the test stimulus is applied to the FPGA function module under test with a second value obtained after the test stimulus is applied to the existing function module, and if the first value and the second value are different, reports an error in simulation; if the first value and the second value are the same, compares the first value with the expected output, if they are different, reports an error in the simulation, and if they are the same, reports that the simulation succeeds (as shown in FIG. 4b, where a comparison module instance is generated as follows: during design of the FPGA function module, if a new function module is a module upgrade on the basis of an existing function module, the existing function module is introduced, as the comparison module instance, in a process of testing the new function module).

In an example, it is assumed that the FPGA function module under test is an embedded 9 K memory module of a new-generation device, which, as a complicated embedded memory module, includes the following parameter characteristics:

1. memory mode: single port (sp), simple dual port (sdp), dual port (tdp);

2. write mode: write_first, read_first, no_change;

3. memory initial value;

4. output register;

5. output register enabling;

6. output register setting and resetting;

7. output latch setting and resetting;

8. output register initial value;

9. output register resetting value;

10. bitwise write enabling, 1-4;

11. chip select signal;

12. bit width of reading data: 1, 2, 4, 9, 18, 36;

13. bit width of writing data: 1, 2, 4, 9, 18, 36;

14. combination of read-write bit widths; and

15. address depth: 8, 9, 10, 11, 12, 13.

Except 3 and 4, all the foregoing parameter characteristics are combined to finally obtain 15552 combinations, that is, full-coverage behavior simulation on the embedded 9 K memory module needs 15552 test cases and corresponding test benches.

For automated test demands, all the parameter characteristics in 1 exist in a behavior model of the embedded 9 K memory module in the form of parameters.

By taking the write mode as an example, expected outputs in test benches corresponding to write_first, read_first, and no_change are different:

1. In the write_first mode, when a write operation is performed on a memory, written new data instantly appears at a read port. In this case, the expected output is a written data stimulus.

2. In the read_first mode, when the write operation is performed on the memory, written data does not appear at the read port, and an output of the read port is storage data before the write address. In this case, the test bench needs to buffer the previous written data stimulus as the expected output.

3. In the no_change mode, when the write operation is performed on the memory, written data does not appear at the read port, and an output of the read port keeps a previous output unchanged. In this case, the test bench needs to buffer an expected output of a previous read operation as the expected output.

Based on the process described above, all the parameter characteristics of the embedded memory module are processed, thereby generating full-test-coverage test cases and test benches.

After completion of generation of all the test cases, the simulation verification system automatically executes all tests and captures a message output in each test process, and outputs a unified test report upon completion of all the tests.

In the embodiment of the present invention, all test cases are acquired based on information about all parameter characteristics of FPGA function modules, thereby establishing a simulation verification system with test coverage reaching 100%.

FIG. 5 is a structural diagram of a simulation verification system for FPGA function modules according to an embodiment of the present invention. As shown in FIG. 5, the system includes a verification bench control center 50 and a simulation test bench 60, where the verification bench control center 50 includes a test case generator 51 and a test bench generator 52; and the simulation test bench 60 includes a random stimulus generator 61 and a comparator 62.

The test case generator 51 is used for generating all test cases by enumerating all parameter characteristics of FPGA function modules.

The test bench generator 52 is used for generating, according to an input type and input parameter characteristics of an FPGA function module under test, a simulation test bench matching configuration of the FPGA function module under test.

The random stimulus generator 61 is used for randomly generating a test stimulus and a corresponding expected output according to the input parameter characteristics of the FPGA function module under test.

The comparator 62 is used for comparing the expected output with an actual output obtained after the test stimulus is applied to the test case corresponding to the FPGA function module under test, and outputting a test report of the FPGA function module under test according to a comparison result.

Further, the comparator 62 is set as a dual comparator, used for determining whether the FPGA function module under test is a module upgraded on the basis of an existing function module, if yes, comparing a first value obtained after the test stimulus is applied to the FPGA function module under test with a second value obtained after the test stimulus is applied to the existing function module, and if the first value and the second value are different, reporting an error in simulation; if the first value and the second value are the same, comparing the first value with the expected output, if they are different, reporting an error in the simulation, and if they are the same, reporting that the simulation succeeds.

In the embodiment of the present invention, all test cases are acquired based on information about all parameter characteristics of FPGA function modules, thereby establishing a simulation verification system with test coverage reaching 100%.

It may be further realized by persons skilled in the art that, units and algorithm steps of each example described in combination with the embodiments disclosed herein can be implemented with electronic hardware, computer software or a combination thereof, and in order to clearly illustrate interchangeability of hardware and software, compositions and steps of the example have been generally described in the foregoing description according to functions. Whether the functions are executed in a mode of hardware or software depends on particular applications and design constraint conditions of the technical solution. Persons skilled in the art can use different methods to implement the described functions for each particular application, but it should not be considered that the implementation goes beyond the scope of the embodiments of the present invention.

The objectives, technical solutions, and beneficial effects of the present invention have been described in further detail in the above specific embodiments. It should be understood that the above descriptions are merely specific embodiments of the present invention, but not intended to limit the protection scope of the present invention. Any modification, equivalent replacement, or improvement made within the spirit and principle of the present invention should fall within the protection scope of the present invention.

What is claimed is:

1. A simulation verification method for Field Programmable Gate Array (FPGA) function modules, comprising:
generating all test cases by enumerating all parameter characteristics of FPGA function modules;
generating, according to an input type and input parameter characteristics of an FPGA function module under test, a simulation test bench matching configuration of the corresponding FPGA function module under test; and
randomly generating, by the simulation test bench, a test stimulus and a corresponding expected output according to the input parameter characteristics of the FPGA function module under test, comparing the expected output with an actual output obtained after the test stimulus is applied to the test case corresponding to the FPGA function module under test, and outputting a test report of the FPGA function module under test according to a comparison result.

2. The method according to claim 1, wherein before the step of comparing the expected output with an actual output obtained after the test stimulus is applied to the test case corresponding to the FPGA function module under test, the method further comprises:
determining whether the FPGA function module under test is a module upgraded on the basis of an existing function module, if yes, comparing a first value obtained after the test stimulus is applied to the FPGA function module under test with a second value obtained after the test stimulus is applied to the existing function module, and if the first value and the second value are different, reporting an error in simulation; if the first value and the second value are the same, comparing the first value with the expected output, if they are different, reporting an error in the simulation, and if they are the same, reporting that the simulation succeeds.

3. A simulation verification system for FPGA function modules, comprising: a verification bench control center, wherein the verification bench control center is used for generating all test cases by enumerating all parameter characteristics of FPGA function modules; and generating, according to an input type and input parameter characteristics of an FPGA function module under test, a simulation test bench matching configuration of the corresponding FPGA function module under test; and randomly generating, by the simulation test bench, a test stimulus and a corresponding expected output according to the input parameter characteristics of the FPGA function module under test, comparing the expected output with an actual output obtained after the test stimulus is applied to the test case corresponding to the FPGA function module under test, and outputting a test report of the FPGA function module under test according to a comparison result,

4. The system according to claim 3, wherein the verification bench control center comprises a test case generator and a test bench generator,
the test case generator is used for generating all test cases by enumerating all parameter characteristics of FPGA function modules; and
the test bench generator is used for generating, according to an input type and input parameter characteristics of an FPGA function module under test, a simulation test bench matching configuration of the FPGA function module under test.

5. The system according to claim 3, wherein the simulation test bench comprises a random stimulus generator and a comparator,
the random stimulus generator is used for randomly generating a test stimulus and a corresponding expected output according to the input parameter characteristics of the FPGA function module under test; and
the comparator is used for comparing the expected output with an actual output obtained after the test stimulus is applied to the test case corresponding to the FPGA function module under test, and outputting a test report of the FPGA function module under test according to a comparison result.

6. The system according to claim 3, wherein the simulation test bench comprises a random stimulus generator and a dual comparator,
the random stimulus generator is used for randomly generating a test stimulus and a corresponding expected output according to the input parameter characteristics of the FPGA function module under test; and
the dual comparator is used for determining whether the FPGA function module under test is a module upgraded on the basis of an existing function module, if yes, comparing a first value obtained after the test stimulus is applied to the FPGA function module under test with a second value obtained after the test stimulus is applied to the existing function module, and if the first value and the second value are different, reporting an error in simulation; if the first value and the second value are the same, comparing the first value with the expected output, if they are different, reporting an error in the simulation, and if they are the same, reporting that the simulation succeeds.
